(19) United States
(12) Patent Application Publication
(10) Pub. No.: US 2026/0190916 A1
(43) Pub. Date: Jul. 2, 2026

(54) SUBSTRATE PROCESSING APPARATUS AND SUBSTRATE PROCESSING METHOD

(71) Applicant: SEMES CO., LTD., Cheonan-si (KR)

(72) Inventors: Ji Su Hong, Seoul (KR); Seung Bum Park, Seoul (KR); Seong Soo Lee, Yongin-si (KR); Hyeon Suk Park, Cheonan-si (KR); Jun Kil Hwang, Yongin-si (KR)

(73) Assignee: SEMES CO., LTD., Cheonan-si (KR)

(21) Appl. No.: 19/432,352

(22) Filed: Dec. 24, 2025

(30) Foreign Application Priority Data
Dec. 27, 2024 (KR) 10-2024-0198527

(51) Int. Cl. H10P 72/00

(52) U.S. Cl. CPC H10P 72/0448; H10P 72/0602; H10P 72/0604

(57) ABSTRACT

Disclosed is a method of processing a substrate. The method includes: supplying a treatment liquid from a treatment liquid supply source that supplies a treatment liquid to a first tank; filtering the treatment liquid by circulating the treatment liquid stored in the first tank through a first circulation line in which a first filter is installed; supplying the treatment liquid from the first tank to a second tank; and liquid-treating the substrate by supplying the treatment liquid stored in the second tank to the substrate, in which when the treatment liquid stored in the first tank is filtered for a set time or longer, the treatment liquid is supplied from the first tank to the second tank, and the set time is set differently depending on the amount of replenishment of the treatment liquid supplied from the treatment liquid supply source to the first tank.

### CROSS-REFERENCE TO RELATED APPLICATION

This application claims priority to and the benefit of Korean Patent Application No. 10-2024-0198527 filed in the Korean Intellectual Property Office on Dec. 27, 2024, the entire contents of which are incorporated herein by reference.

### TECHNICAL FIELD

The present invention relates to a substrate processing apparatus and a substrate processing method, and more particularly, to a substrate processing apparatus and a substrate processing method that are capable of improving the efficiency of filtering a treatment liquid supplied at a high temperature.

### BACKGROUND ART

The semiconductor manufacturing process includes a wet process of processing a substrate with a treatment liquid. In this process, a high-temperature treatment liquid may be used. However, the use of high-temperature treatment liquid may cause a problem of lowering filter efficiency.

The performance degradation of filters in a high-temperature environment is caused by several factors. The filter material may undergo structural deformation due to thermal expansion, which affects the pore size and distribution of the filter. In addition, at high temperatures, the chemical reaction rate increases, and the interaction between the filter material and the treatment liquid becomes more active, thereby changing the physical and chemical properties of the filter.

If the treatment liquid is not sufficiently filtered due to such a decrease in filter efficiency, defects, such as particles, may occur on the substrate. Consequently, it causes the stability and efficiency of the process to decrease.

### SUMMARY OF THE INVENTION

The present invention has been made in an effort to provide a substrate processing apparatus and a substrate processing method capable of preventing a decrease in filtration efficiency of a filter even if a substrate is processed using a high-temperature treatment liquid.

The present invention has also been made in an effort to provide a substrate processing apparatus and a substrate processing method capable of minimizing foreign substances, such as particles, in a treatment liquid even if the substrate is processed using a high-temperature treatment liquid.

The objectives of the present disclosure are not limited thereto and other objectives not stated herein may be clearly understood by those skilled in the art from the following description.

An exemplary embodiment of the present disclosure, a method of processing a substrate, the method comprising: supplying a treatment liquid from a treatment liquid supply source that supplies a treatment liquid to a first tank; filtering the treatment liquid by circulating the treatment liquid stored in the first tank through a first circulation line in which a first filter is installed; supplying the treatment liquid from the first tank to a second tank; and liquid-treating the substrate by supplying the treatment liquid stored in the second tank to the substrate, wherein when the treatment liquid stored in the first tank is filtered for a set time or longer, the treatment liquid is supplied from the first tank to the second tank, and the set time may be set differently depending on the amount of replenishment of the treatment liquid supplied from the treatment liquid supply source to the first tank.

Further, an exemplary embodiment of the present disclosure, an apparatus for processing a substrate, the apparatus comprising: a liquid treating chamber for processing a substrate by supplying a treatment liquid to a substrate loaded into an inner side; and a liquid supply unit for supplying the treatment liquid to the liquid treating chamber, wherein the liquid supply unit includes: a treatment liquid supply source for storing the treatment liquid; a treatment liquid supply pipe for supplying the treatment liquid from the treatment liquid supply source to a first tank; the first tank for receiving the treatment liquid from the treatment liquid supply source and storing the treatment liquid; a second tank for receiving the treatment liquid from the first tank and storing the treatment liquid; and a controller, and the first tank includes: a first tank body having a first inner space in which the treatment liquid is stored; a first circulation line that is connected to the first tank body and circulates the treatment liquid stored in the first inner space; a first filter installed in the first circulation line; and a first supply pipe for supplying the treatment liquid from the first tank to the second tank, the second tank includes a liquid supply pipe for supplying the treatment liquid stored in the second tank to the liquid treating chamber, and when the second tank is replenished with the treatment liquid from the first tank, the controller controls the replenishment of the treatment liquid to be performed when the treatment liquid is circulated through a first circulation line in the first tank for a set time or longer, and the set time may be set differently depending on the amount of the treatment liquid replenished in the first tank from the treatment liquid supply source.

Further, an exemplary embodiment of the present disclosure, a method of processing a substrate by using a substrate processing apparatus including: a liquid treating chamber that processes a substrate by supplying a treatment liquid to a substrate loaded into an inner side; and a liquid supply unit for supplying the treatment liquid to the liquid treating chamber, the liquid supply unit including: a treatment liquid supply source for storing the treatment liquid; a treatment liquid supply pipe for supplying the treatment liquid from the treatment liquid supply source to a first tank; the first tank for receiving the treatment liquid from the treatment liquid supply source and storing the treatment liquid; a second tank for receiving the treatment liquid from the first tank and storing the treatment liquid; and a third tank for receiving the treatment liquid from the second tank and storing the treatment liquid, the first tank including: a first tank body having a first inner space in which the treatment liquid is stored; a first circulation line that is connected to the first tank body and circulates the treatment liquid stored in the first inner space; a first filter and a first heater installed in the first circulation line; and a first supply pipe for supplying the treatment liquid from the first tank to the second tank, the second tank including: a second tank body having a second inner space in which the treatment liquid is stored; a second circulation line that is connected to the second tank body and circulates a raw liquid of the treatment liquid stored in the second inner space; a second filter and a second heater installed in the second circulation line; a second supply pipe for supplying the treatment liquid stored in the second tank to the liquid treating chamber; and a second level sensor for measuring a water level of the treatment liquid in the second inner space, and the third tank including: a third tank body having a third inner space in which the treatment liquid is stored; a third circulation line that is connected to the third tank body and circulates the treatment liquid stored in the third inner space; a third supply pipe for supplying the treatment liquid from the third tank to the liquid treating chamber; and a third filter and a third heater installed in the third circulation line, the method comprising: supplying a treatment liquid from the treatment liquid supply source to the first tank; filtering the treatment liquid by circulating the treatment liquid stored in the first tank through the first circulation line; supplying the treatment liquid from the first tank to the second tank; supplying the treatment liquid from the second tank to the third tank; and processing the substrate by supplying the treatment liquid stored in the second tank to the substrate, wherein when the treatment liquid stored in the first tank is filtered for a set time or longer, the treatment liquid is supplied from the first tank to the second tank, and the set time may be longer as the amount of replenishment of the treatment liquid supplied from the treatment liquid supply source to the first tank increases.

According to the exemplary embodiment of the present invention, it is possible to prevent a decrease in filtration efficiency of a filter even if a substrate is processed using a high-temperature treatment liquid.

Further, according to the exemplary embodiment of the present invention, it is possible to minimize foreign substances, such as particles, in a treatment liquid even if the substrate is processed using a high-temperature treatment liquid.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram illustrating a treatment liquid supply unit according to the exemplary embodiment of the present invention.

FIG. 4 is a diagram illustrating a treatment liquid supply unit according to the exemplary embodiment of the present invention.

FIG. 5 is a diagram schematically illustrating the treatment liquid supply unit of FIG. 3 according to another exemplary embodiment.

FIG. 6 is a diagram schematically illustrating the treatment liquid supply unit of FIG. 3 according to still another exemplary embodiment.

FIG. 7 is a diagram schematically illustrating the liquid treating chamber of FIG. 1 according to another exemplary embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the

### Disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be treated. However, the technical idea of the present invention may be applied to devices used for treating other types of substrates other than wafers as objects to be treated.

Hereinafter, a substrate processing apparatus and a substrate processing method according to the present invention will be described with reference to the accompanying drawings. The description of the substrate processing apparatus deals with the structure and function of each component of the substrate processing apparatus, and the description of the substrate processing method deals with a method of controlling these components. The description of each component includes structural characteristics and operation methods, and thus the operating principle of the substrate processing apparatus may be clearly understood.

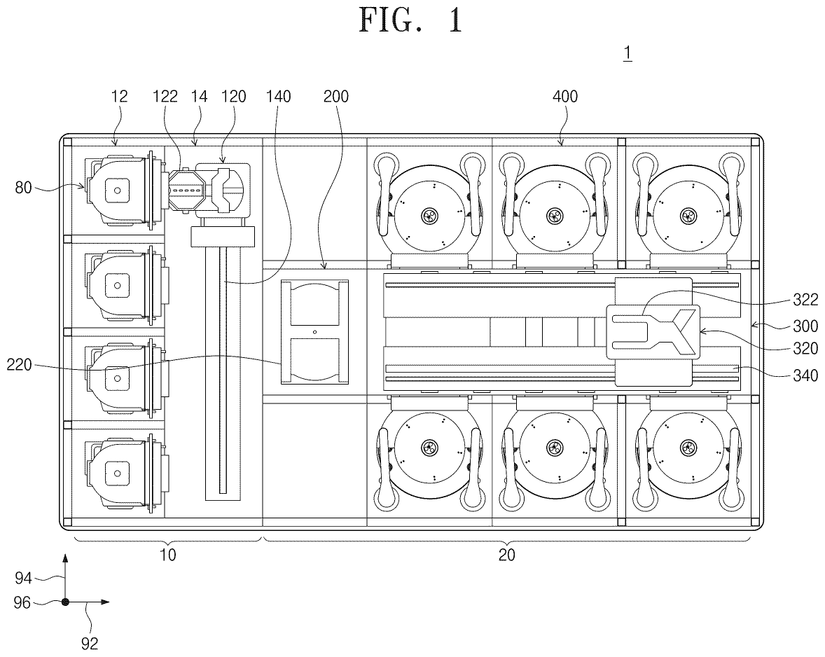

FIG. 1 is a top plan view schematically illustrating a substrate processing apparatus according to an exemplary embodiment of the present invention. Referring to FIG. 1, a substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96. The controller 30 is provided to control all operable components of the substrate processing apparatus. Accordingly, the controller 30 enables efficient operation and management of the substrate processing apparatus.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer chamber 200, a transfer chamber 300, and a process chamber 400.

The buffer chamber 200 provides a space in which the substrate W loaded into the treating module 20 and the substrate W unloaded from the treating module 20 stay temporarily. The buffer chamber 200 includes a plurality of buffers 220 on which the substrate W is temporarily placed. The buffers 220 may be disposed while being spaced apart from each other in the third direction 96. A front face and a rear face of the buffer chamber 200 are opened. The front face is a face facing the index module 10, and the rear face is a face facing the transfer chamber 300. The index robot 120 may approach the buffer chamber 200 through the front face, and the transfer robot 320 may approach the buffer chamber 200 through the rear face.

The transfer chamber 300 transfers the substrate W between the buffer chamber 200 and the liquid treating chamber 400. The transfer chamber 300 may be provided so that a longitudinal direction is the first direction 92. The buffer chamber 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer chamber 200 may be located at one end of the transfer chamber 300. The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forward and backward.

The process chamber 400 performs a process of processing the substrate W loaded into the process chamber 400. According to an example, the process chamber 400 performs a process of liquid-treating the substrate W by supplying a treatment liquid onto the substrate W. The treatment liquid may be various types of liquids used in a wet etching process or a cleaning process for removing a film on the surface of the substrate W. The treatment liquid may be at least one selected from hydrofluoric acid (HF), sulfuric acid (H₃SO₄), hydrogen peroxide (H₂O₂), a mixture solution containing hydrogen peroxide (H₂O₂), nitric acid (HNO₃), phosphoric acid (H₃PO₄), ozone water, SC-1 solution (a mixture solution of ammonium hydroxide (NH₄OH), hydrogen peroxide (H₂O₂), and water (H₂O)), and the like. According to an example, the treatment liquid may be an etching liquid for etching titanium nitride (TiN). However, the present invention is not limited thereto, and the treatment liquid may be various other types of treatment liquids which may be used in the substrate processing process. Hereinafter, the present invention will be described based on the case where the process chamber 400 is a liquid treating chamber for processing the substrate W with at least one of the foregoing treatment liquids as an example.

A plurality of liquid treating chambers 400 is provided. The liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

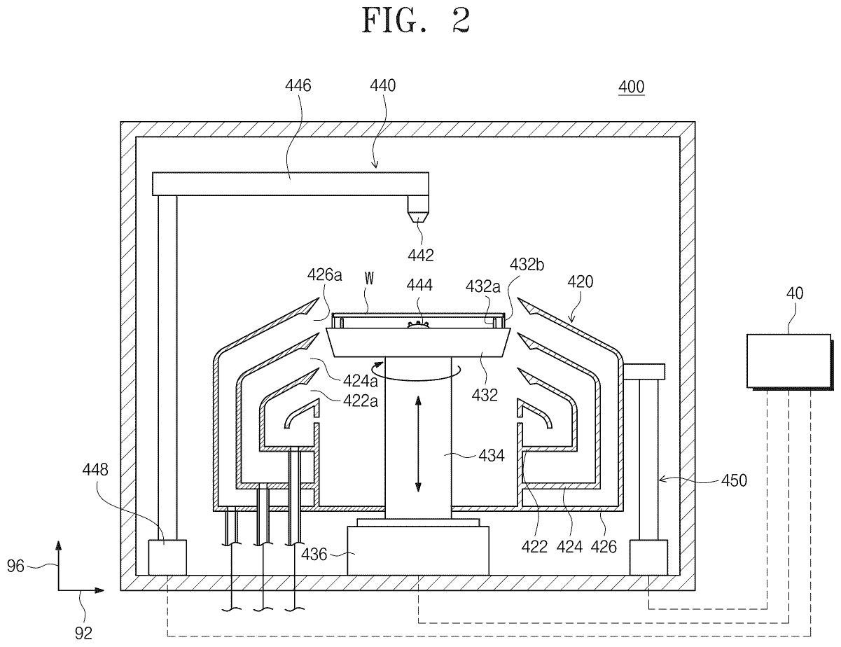

FIG. 2 is a diagram schematically illustrating the liquid treating chamber 400 of FIG. 1 according to the exemplary embodiment. Referring to FIG. 2, the liquid treating chamber 400 includes a housing 410, a cup body 420, a support unit 430, a nozzle unit 440, a lifting unit 450, a treatment liquid recovery unit 500, and a controller.

The housing 410 is provided in a generally rectangular parallelepiped shape. The cup body 420, the support unit 430, and the nozzle unit 440 are disposed within the housing 410.

The cup body 420 has a treatment space with an open top, and the substrate W is liquid-processed in the treatment space. The support unit 430 supports the substrate W in the treatment space. The nozzle unit 440 supplies a liquid onto the substrate W supported on the support unit 430. The liquid may be provided in a plurality of types, and may be sequentially supplied onto the substrate W. The lifting unit 450 adjusts a relative height between the cup body 420 and the support unit 430.

According to an example, the cup body 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 430. As the liquid treating process proceeds, the treatment liquid scattered by the rotation of the substrate W is introduced into the recovery space through the inlets 422a, 424a, and 426a of the respective recovery containers 422, 424, and 426. According to the example, the cup body 420 includes a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 430 includes a support plate 432 and a drive shaft 434. An upper surface of the support plate 432 may be provided in a generally circular shape, and may have a diameter larger than a diameter of the substrate W. Further, a support pin 432a supporting the rear surface of the substrate W is provided at the center of the support plate 432, and the upper end of the support pin 432a is provided to protrude from the support plate 432 so that the substrate W is spaced apart from the support plate 432 by a predetermined distance. A chuck pin 432b is provided at an edge of the support plate 432. The chuck pin 432b is provided to protrude upward from the support plate 432, and supports the side portion of the substrate W so that the substrate W does not deviate from the support unit 430 when the substrate W is rotated. The drive shaft 434 is driven by the driver 436, is connected to the center of the bottom surface of the substrate W, and rotates the support plate 432 about its central axis.

The nozzle unit 440 discharges the treatment liquid supplied from the treatment liquid supply unit 600 onto the substrate W. The nozzle unit 440 may include a first nozzle 442, a second nozzle 444, a nozzle support 446, and a nozzle driver 448.

The first nozzle 442 supplies the treatment liquid to the substrate W supported by the support unit 430. The first nozzle 442 is supported by the nozzle support 446. The nozzle driver 448 may change the position of the first nozzle 442 by driving the nozzle support 446.

The second nozzle 444 may be a back nozzle that supplies a treatment liquid to the bottom surface of the substrate W supported by the support unit 430. The second nozzle 444 may be provided in a central region of the support plate 432.

To discharge a plurality of treatment liquids simultaneously or sequentially onto the substrate W, the nozzle unit 440 may further include one or more nozzles. Optionally, the nozzle unit 440 may further include one or a plurality of nozzles in addition to the first nozzle 442 and the second nozzle 444. The added nozzle may supply another type of treatment liquid to the substrate. For example, another type of treatment liquid may be an acid solution or a base solution for removing foreign substances on the substrate. In addition, another type of treatment liquid may be alcohol having surface tension lower than water. For example, the alcohol may be isopropyl alcohol. The added nozzle may be supported by the nozzle support 446 or may be supported by different nozzle supports. Accordingly, the first nozzle 442 and the added nozzle may be moved independently or together.

The lifting unit 450 moves the cup body 420 in the up and down direction. By the up and down movement of the cup body 420, a relative height between the cup body 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup body 420 is fixedly installed, and the lifting unit 450 may move the support unit 430 in the vertical direction.

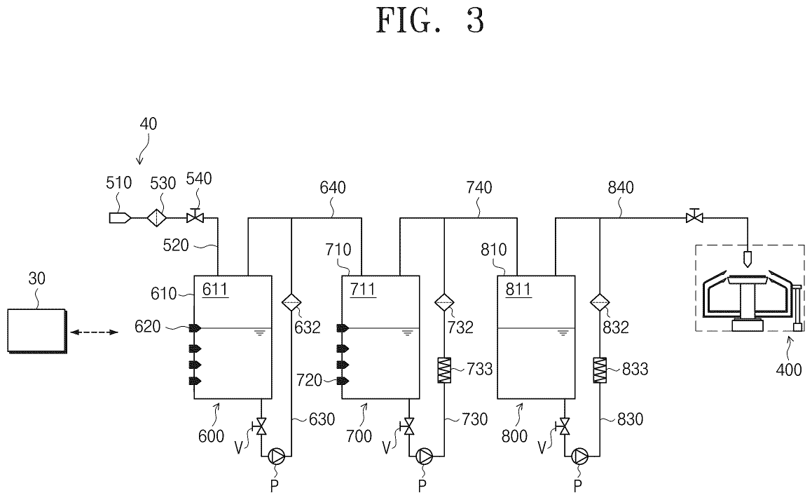

In addition, the treating module 20 may further include a treatment liquid supply unit 40 to supply a treatment liquid to the liquid treating chamber 400. FIG. 3 is a diagram illustrating the treatment liquid supply unit 40 according to the exemplary embodiment of the present invention. Hereinafter, components included in the liquid supply unit 40 will be described with reference to FIG. 3.

The treatment liquid supply source 510 stores and supplies the treatment liquid. The treatment liquid supply source 510 supplies the treatment liquid through the treatment liquid supply pipe 520. The treatment liquid supply source 510 is connected to a first tank 600 through a treatment liquid supply pipe 520.

The treatment liquid supply pipe 520 is provided to supply the treatment liquid from the treatment liquid supply source 510 to the first tank 600. In the treatment liquid supply pipe 520, a filter 530 and a valve 540 may be installed. Additionally, a configuration (e.g., a pump) required for supplying the treatment liquid may be installed in the treatment liquid supply pipe 520.

The first tank 600 is connected to the treatment liquid supply pipe 520. The first tank 600 receives a treatment liquid from the treatment liquid supply source 510. The first tank 600 stores the supplied treatment liquid. The first tank 600 supplies the treatment liquid to a second tank 700. The first tank 600 may include a first tank body 610, a first level sensor 620, a first circulation line 630, a first filter 632, and a first supply pipe 640.

The first tank body 610 has a first inner space 611. The treatment liquid supplied to the first tank 600 may be stored in the first inner space 611. The first tank body 610 may be provided in a closed structure.

A first level sensor 620 may be installed in the first tank body 610. The first level sensor 620 may measure the water level of the treatment liquid stored in the first inner space 611. The first level sensor 620 may measure the water level of the treatment liquid by dividing the water level of the treatment liquid into several stages. According to an example, the water level of the treatment liquid may be measured by subdividing the level into four stages.

The water levels of the four stages may be divided into an H level (high operating level), an MR level (middle refill operating level), an M level (middle operating level), and an L level (low operating level). When the water level of the treatment liquid becomes less than each level, the first level sensor 620 may be set to turn off a flashing light corresponding to each level. The operation in the first tank 600 may be determined according to whether the flashing light is on or off. For example, the H level may be used as a replenishment limit line. The treatment liquid may be replenished up to the replenishment limit line. When the treatment liquid reaches the H level, a corresponding flashing light is turned on, and replenishment of the treatment liquid may be stopped. The M level may be used as a replenishment reference line. When the water level of the treatment liquid is lowered and the flashing light corresponding to the M level is turned off, replenishment of the treatment liquid to the first tank 600 may be requested. The MR level may be used as a supply limit line. The treatment liquid may be supplied to the second tank 700 until it reaches the supply limit line. When the water level of the treatment liquid is lowered and the flashing light corresponding to the MR level is turned off, the supply to the second tank 700 may be stopped. The L level may be used as a circulation limit line. The treatment liquid may circulate to the circulation limit line. When the water level of the treatment liquid is lowered and the flashing light corresponding to the L level is turned off, the circulation operation flowing along the first circulation line 630 may be stopped.

The first circulation line 630 is connected to the first tank body 610. The first circulation line 630 may be provided so that the treatment liquid circulates to the outside of the first tank body 610. According to an example, the first circulation line 630 may be provided so that the treatment liquid flows out from the lower surface of the first tank body 610 and flows into the upper surface of the first tank body 610. The first filter 632 is installed on the first circulation line 630.

The first filter 632 may filter the treatment liquid circulating through the first circulation line 630. The first filter 632 may remove impurities, such as particles, from the treatment liquid. The treatment liquid circulating through the first circulation line 630 may not be heated. The treatment liquid circulating through the first circulation line 630 may be room temperature. Accordingly, the first filter 632 may filter the treatment liquid without deteriorating the filtering performance of the first filter 632 due to high temperature.

In general, a circulation line is installed in a tank supplying the treatment liquid, and the treatment liquid flowing along the circulation line is heated by the heater. According to the exemplary embodiment of the present invention, a heating means for heating the treatment liquid may not be installed to prevent a decrease in the filtration efficiency of the first filter 632. Accordingly, it is possible to reduce the installation and maintenance cost of the heating means.

In addition, components required for the flow of the treatment liquid may be further installed in the first circulation line 630. According to an example, a first pump P, a valve V, and the like may be further installed in the first circulation line 630.

The first supply pipe 640 connects the first tank 600 and the second tank 700. The first supply pipe 640 is provided to supply the treatment liquid from the first tank 600 to the second tank 700. According to an example, the first supply pipe 640 may be installed on the first circulation line 630.

The second tank 700 is connected to the first supply pipe 640. The second tank 700 receives the treatment liquid from the first tank 600. The second tank 700 stores the supplied treatment liquid. The second tank 700 supplies the treatment liquid to the third tank 800. The second tank 700 may include a second tank body 710, a second level sensor 720, a second circulation line 730, a second filter 732, and a second supply pipe 740.

The second tank body 710 has a second inner space 711. The treatment liquid supplied to the second tank 700 may be stored in the second inner space 711. The second tank body 710 may be provided in a closed structure.

The second level sensor 720 may be installed in the second tank body 710. The second level sensor 720 may measure the water level of the treatment liquid stored in the second inner space 711. The second level sensor 720 may be provided to be identical to the first level sensor 620.

The second circulation line 730 is connected to the second tank body 710. The second circulation line 730 may be provided so that the treatment liquid circulates to the outside of the second tank body 710. According to an example, the second circulation line 730 may be provided so that the treatment liquid flows out from the lower surface of the second tank body 710 and flows into the upper surface of the second tank body 710. A second heater 733 and the second filter 732 are installed on second first circulation line 730.

The second filter 733 may filter the treatment liquid circulating through the second circulation line 730. The second heater 733 may heat the treatment liquid at a second temperature. The second heater 733 may be a line heater. For example, the second temperature may be 30° C. to 100° C.

The second filter 732 may filter the treatment liquid circulating through the second circulation line 730. The second filter 732 may remove impurities, such as particles, from the treatment liquid. The treatment liquid circulating through the second circulation line 730 may be high temperature. Accordingly, the filtering performance of the second filter 732 may be deteriorated due to the high temperature.

In addition, components required for the flow of the treatment liquid may be further installed in the second circulation line 730. According to an example, a pump P, a valve V, and the like may be further installed in the second circulation line 730.

The second supply pipe 740 connects the second tank 700 and the third tank 800. The second supply pipe 740 is provided to supply the treatment liquid from the second tank 700 to the third tank 800. According to an example, the second supply pipe 740 may be installed on the second circulation line 730.

The third tank 800 is connected to the second supply pipe 740. The third tank 800 receives the treatment liquid from the second tank 700. The third tank 800 stores the supplied treatment liquid. The third tank 800 supplies the treatment liquid to the third tank 800. The third tank 800 may include a third tank body 810, a third circulation line 830, a third filter 832, and a third supply pipe 840.

The third tank body 810 has a third inner space 811. The treatment liquid supplied to the third tank 800 may be stored in the third inner space 811. The third tank body 810 may be provided in a closed structure.

The third circulation line 830 is connected to the third tank body 810. The third circulation line 830 may be provided so that the treatment liquid circulates to the outside of the third tank body 810. According to an example, the third circulation line 830 may be provided so that the treatment liquid flows out from the lower surface of the third tank body 810 and flows into the upper surface of the third tank body 810. The third filter 832 is installed on the third circulation line 830.

The third filter 833 may filter the treatment liquid circulating through the third circulation line 830. The third heater 833 may heat the treatment liquid at the second temperature. The third heater 833 may be a line heater. For example, the second temperature may be 30° C. to 100° C.

The third filter 832 may filter the treatment liquid circulating through the third circulation line 830. The third filter 832 may remove impurities, such as particles, from the treatment liquid. The treatment liquid circulating through the third circulation line 830 may be high temperature. Accordingly, the filtering performance of the third filter 832 may be deteriorated due to the high temperature.

The liquid supply pipe 840 connects the third tank 800 to the liquid treating chamber 400. The third supply pipe is provided to supply the treatment liquid from the third tank 800 to the liquid treating chamber 400. According to an example, the liquid supply pipe 840 may be installed in the third circulation line 830.

In addition, components required for the flow of the treatment liquid may be further installed in the third circulation line 830. According to an example, a pump P and a valve V may be further installed in the third circulation line 830.

The controller 30 may effectively manage and execute the entire substrate processing process, such as movement of the substrate W, position adjustment, and processing process execution, by precisely controlling each component of the index module 10 and the treating module 20. The controller 30 adjusts the operation of each component according to the stored processing recipe, and selectively analyzes information received from the sensor to optimize the processing process in real time. Accordingly, the controller 30 enables substrate processing with high precision and consistency.

The controller 30 includes a process controller, a user interface, and a storage unit. The process controller is composed of a microprocessor (computer) and executes overall control of the substrate processing apparatus. In this process, the process controller receives data from various sensors in the apparatus, monitors and controls the processing situation in real time. The process controller is electrically connected to the sensor, and may receive information by wire or wirelessly. The storage unit stores a control program and a processing recipe. The control program manages processing executed in the substrate processing apparatus under the control of the process controller. The processing recipe is a program for executing processing to each component according to various data and processing conditions. The user interface and the storage unit are connected to the process controller. The processing recipe is stored in a storage medium in the storage unit, which may be a portable disk such as a hard disk, a CD-ROM, a DVD, or a semiconductor memory such as a flash memory. The user interface and the storage unit are connected to the process controller.

Hereinafter, a method of processing a substrate will be described. The substrate processing method described below may be performed by the substrate processing apparatus described with reference to FIGS. 1 to 3. Accordingly, hereinafter, a substrate processing method according to an exemplary embodiment will be described by referring to reference numerals illustrated in FIGS. 1 to 3. In addition, the substrate processing method described below may be performed by controlling, by the controller, the configurations included in the substrate processing apparatus described above.

The treatment liquid is supplied from the treatment liquid supply source 510 to the first tank 600. The treatment liquid may be supplied to supplement the consumed treatment liquid after processing the substrate W with the treatment liquid. In addition, the treatment liquid may be supplied after exchanging the treatment liquid. The treatment liquid supply source 510 may supply the treatment liquid to a certain level. According to an example, the treatment liquid may be supplied until the water level of the treatment liquid measured by the first level sensor 620 reaches the H level.

The treatment liquid supplied to the first tank 600 is circulated to the first circulation line 630. When the first heater 633 is not installed in the first circulation line 630, the treatment liquid flowing through the first circulation line 630 may be room temperature. Alternatively, when the first heater 633 is installed in the first circulation line 630, the treatment liquid flowing through the first circulation line 630 may be heated to a first temperature by the first heater 633. The first temperature may be a temperature that does not decrease the filtration efficiency of the filter.

The treatment liquid supplied to the first circulation line 630 is filtered by the first filter 632. The treatment liquid may be continuously circulated for a set time and filtered. The set time may be a time when impurities in the treatment liquid are filtered by the first filter 632 to reach a certain level or less. The set time may be set differently according to the replenishment amount of the treatment liquid supplied to the first tank 600. The set time may be provided longer as the replenishment amount of the treatment liquid supplied to the first tank 600 increases. The set time may be set according to the water level determined by the first level sensor 620. For example, the set time when the treatment liquid is replenished after the flashing light corresponding to the M level is turned off may be shorter than the set time when the treatment liquid is replenished after the flashing light corresponding to the L level is turned off.

The set time may be a reference for supplying the treatment liquid from the first tank 600 to the second tank 700. Even if the water level of the treatment liquid stored in the second tank 700 falls to a water level requiring replenishment of the treatment liquid, if the treatment liquid is not filtered by the first filter 632 for a set time, the treatment liquid may not be supplied from the first tank 600 to the second tank 700.

When the set time has elapsed and the replenishment of the second tank 700 with the treatment liquid is required, the treatment liquid is supplied from the first tank 600 to the second tank 700. The treatment liquid is supplied to the second tank 700 through the first supply pipe 640.

The treatment liquid supplied to the second tank 700 circulates through the second circulation line 730. The treatment liquid may be heated by the second heater 733 installed on the second circulation line 730. The treatment liquid may be heated to a set temperature. The set temperature may be a temperature required to process the substrate W. The set temperature may be a temperature required by a treatment recipe. According to an example, the second temperature may be the set temperature. The second temperature may be a temperature higher than the first temperature. Also, the second temperature may be a temperature higher than room temperature.

Further, the treatment liquid may be filtered by the second filter 732 installed on the second circulation line 730. When the treatment liquid is at a high temperature, the filtration performance of the second filter 732 may be deteriorated. However, since the treatment liquid is primarily filtered by the first filter 632, even if the filtration performance of the second filter 732 is deteriorated, impurities in the treatment liquid may be effectively removed and the treatment liquid is supplied to the substrate W.

Thereafter, the treatment liquid stored in the second tank 700 is supplied to the third tank 800. The treatment liquid supplied to the third tank 800 circulates through the third circulation line 830. The treatment liquid may be heated by the third heater 833 installed on the third circulation line 833. Even if the treatment liquid is heated by the second heater 733, the temperature of the treatment liquid may be lowered in the process in which the treatment liquid is supplied to the third tank 800 or may be supplied to the third tank 800 in a state in which the treatment liquid is not sufficiently heated. Accordingly, the third heater 833 may undergo a process of heating the treatment liquid again. The treatment liquid may be heated to a set temperature. The set temperature may be a temperature required to process the substrate W. The set temperature may be a temperature required by a treatment recipe. According to an example, the second temperature may be the set temperature. The second temperature may be a temperature higher than the first temperature. Also, the second temperature may be a temperature higher than room temperature. When the treatment liquid is heated to a set temperature, the treatment liquid may be supplied from the third tank 800 to the liquid treating chamber 400.

After supplying the treatment liquid to the liquid treating chamber 400 and/or during supplying, the first tank 600 may be replenished with the treatment liquid. The substrate processing method described above may be repeatedly performed together with replenishment of the first tank 600 with the treatment liquid.

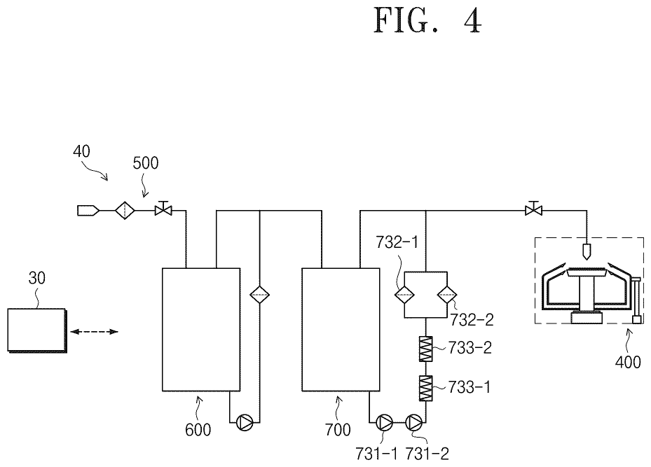

FIG. 4 is a diagram illustrating a treatment liquid supply unit according to another exemplary embodiment of the present invention. Hereinafter, the liquid supply unit will be described with reference to FIG. 4. Although a description is made by referring to reference numerals illustrated in FIGS. 1 to 3, descriptions of overlapping components will be omitted.

Referring to FIG. 4, a liquid supply unit according to another exemplary embodiment of the present invention may include only the first tank 600 and the second tank 700. The second supply pipe 740 may be the liquid supply pipe 840, and the liquid supply pipe 840 may connect the second tank 700 to the liquid treating chamber 400. Accordingly, the treatment liquid may be supplied from the second tank 700 to the liquid treating chamber 400. Also, a plurality of second filters 732 and second heaters 733 may be provided. According to an example, a plurality of second filters 732 may be connected in parallel, and a plurality of second heaters 733 may be connected in series.

In general, when a high-temperature treatment liquid is supplied, the performance of the filter may be deteriorated because the treatment liquid is heated in the entire path for supplying the treatment liquid. However, according to the exemplary embodiment of the present invention, the filtration process and the heating process of the treatment liquid may be performed separately. For example, the treatment liquid may be filtered in the first tank 600, and the treatment liquid may be heated in the second tank 700 and the third tank 800. Accordingly, it is possible to prevent the performance of the filter from deteriorating due to the high-temperature treatment liquid and thus the filtration efficiency from deteriorating. In addition, by setting a set time in consideration of the degree of contamination of the treatment liquid according to the new replenishment amount into the first tank 600, impurities in the treatment liquid may be efficiently removed. Accordingly, process defects due to impurities may be prevented, and this greatly contributes to productivity improvement and quality improvement. In addition, the life of the first filter 620 may be extended, thereby reducing maintenance costs.

In the above-described example, the present invention has been described based on the case where the treatment liquid is heated by the heater installed in each circulation line as an example. However, the present invention is not limited thereto, and a means for heating the treatment liquid may also be provided in each tank.

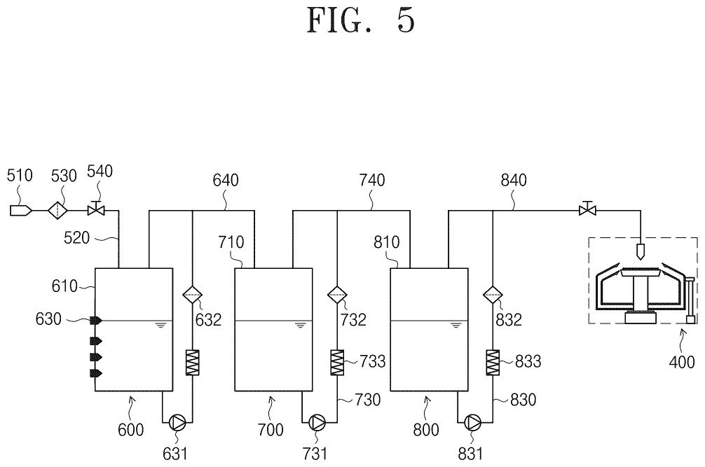

In addition, in the above-described example, the present invention has been described in the case where the heating means for heating the treatment liquid is not installed in the first circulation line 630 as an example. However, the present invention is not limited thereto, and the first heater 633 for heating the treatment liquid may be installed as illustrated in FIG. 5. The first heater 633 is provided to heat the treatment liquid to a first temperature. The first temperature may be lower than a second temperature to be described later. Also, the first temperature may be a temperature that belongs to a specification required by the first filter 632.

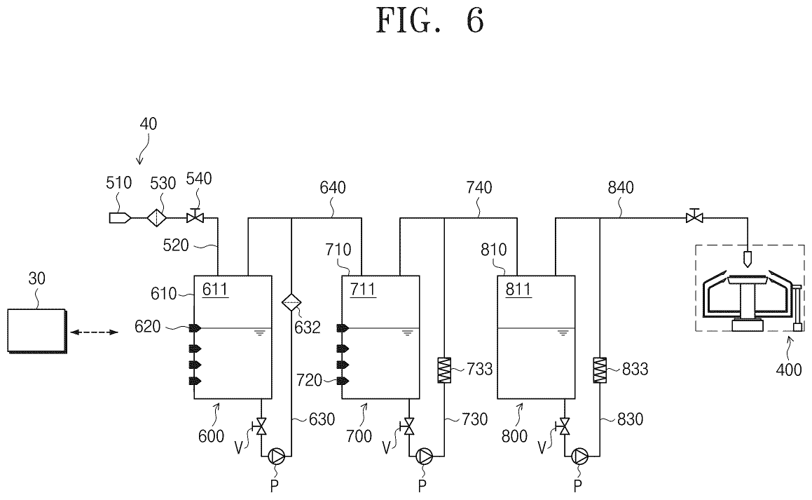

In addition, in the above-described example, the present invention has been described based on the case where the second filter 732 and the third filter 832 are provided as an example. However, the present invention is not limited thereto, and as illustrated in FIG. 6, the second filter 732 and the third filter 832 may not be installed. Since the high-temperature treatment liquid deteriorates filtering performance of the filter, installation of the second filter 732 and the third filter 832 may be omitted. Even if the second filter 732 and the third filter 832 are omitted, since the treatment liquid is filtered by the first filter 632, problems, such as process defects, may not be caused. By omitting the second filter 732 and the third filter 832, it is possible to reduce costs for installation and maintenance of the second filter 732 and the third filter 832.

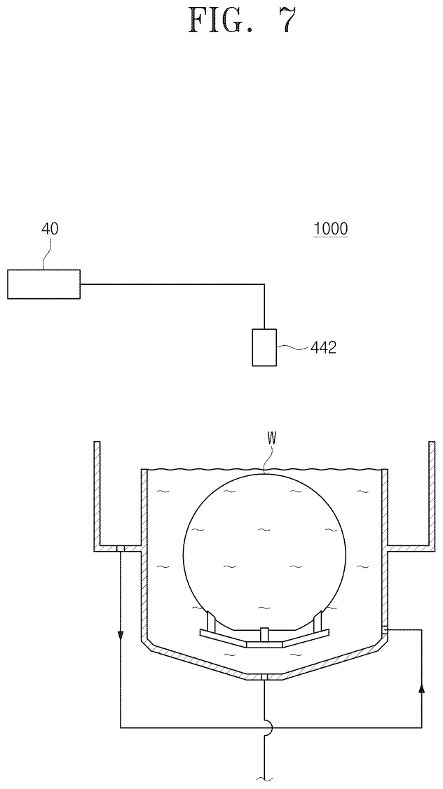

In addition, in the aforementioned example, the liquid treating chamber 400 is described as a single wafer type that liquid-treats a single substrate W, but as illustrated in FIG. 7, the liquid treating chamber 100 may be provided as a batch-type liquid treating chamber 1000 that may liquid-treat the plurality of substrates Ws at the same time.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A method of processing a substrate, the method comprising:
supplying a treatment liquid from a treatment liquid supply source that supplies a treatment liquid to a first tank;
filtering the treatment liquid by circulating the treatment liquid stored in the first tank through a first circulation line in which a first filter is installed;
supplying the treatment liquid from the first tank to a second tank; and
liquid-treating the substrate by supplying the treatment liquid stored in the second tank to the substrate,
wherein when the treatment liquid stored in the first tank is filtered for a set time or longer, the treatment liquid is supplied from the first tank to the second tank, and
the set time is set differently depending on the amount of replenishment of the treatment liquid supplied from the treatment liquid supply source to the first tank.

2. The method of claim 1, wherein the set time is longer as the amount of replenishment of the treatment liquid supplied from the treatment liquid supply source to the first tank increases.

3. The method of claim 1, wherein when a water level of the treatment liquid in the second tank is less than a preset water level, the treatment liquid is supplied from the first tank to the second tank, and
when the treatment liquid is not circulated in the first tank for the set time or longer, the treatment liquid is not supplied from the first tank to the second tank.

4. The method of claim 1, wherein the treatment liquid stored in the second tank is circulated through a second circulation line in which a second heater is installed to heat the treatment liquid to a second temperature.

5. The method of claim 1, wherein the treatment liquid stored in the first tank is circulated through the installed first circulation line so that the treatment liquid is not heated.

6. The method of claim 1, wherein the treatment liquid flowing through the first circulation line is at room temperature.

7. The method of claim 4, wherein the treatment liquid stored in the first tank is circulated through the first circulation line in which the first heater is installed to heat the treatment liquid to the first temperature.

8. The method of claim 7, wherein the second temperature is higher than the first temperature.

9. The method of claim 8, wherein the treatment liquid is filtered by circulating the treatment liquid stored in the second tank through the second circulation line in which the second filter is installed.

10. The method of claim 1, wherein the treatment liquid stored in the second tank is supplied to the substrate through a third tank, and
the treatment liquid supplied to the third tank is circulated through a third circulation line in which a third filter and a third heater are installed to filter and heat the treatment liquid and supply the filtered and heated treatment liquid to the substrate.

11. An apparatus for processing a substrate, the apparatus comprising:
a liquid treating chamber for processing a substrate by supplying a treatment liquid to a substrate loaded into an inner side; and
a liquid supply unit for supplying the treatment liquid to the liquid treating chamber,
wherein the liquid supply unit includes:
a treatment liquid supply source for storing the treatment liquid;
a treatment liquid supply pipe for supplying the treatment liquid from the treatment liquid supply source to a first tank;
the first tank for receiving the treatment liquid from the treatment liquid supply source and storing the treatment liquid;
a second tank for receiving the treatment liquid from the first tank and storing the treatment liquid; and
a controller, and
the first tank includes:
a first tank body having a first inner space in which the treatment liquid is stored;
a first circulation line that is connected to the first tank body and circulates the treatment liquid stored in the first inner space;
a first filter installed in the first circulation line; and
a first supply pipe for supplying the treatment liquid from the first tank to the second tank,
the second tank includes a liquid supply pipe for supplying the treatment liquid stored in the second tank to the liquid treating chamber, and
when the second tank is replenished with the treatment liquid from the first tank, the controller controls the replenishment of the treatment liquid to be performed when the treatment liquid is circulated through a first circulation line in the first tank for a set time or longer, and
the set time is set differently depending on the amount of the treatment liquid replenished in the first tank from the treatment liquid supply source.

12. The apparatus of claim 11, wherein as the amount of replenishment of the treatment liquid increases, the set time is provided longer.

13. The apparatus of claim 11, wherein the second tank includes:
a second tank body having a second inner space in which the treatment liquid is stored;
a second circulation line that is connected to the second tank body and circulates a raw liquid of the treatment liquid stored in the second inner space; and
a second level sensor for measuring a water level of the treatment liquid in the second inner space, and
when the water level of the treatment liquid in the second tank is less than a preset water level, the controller controls the treatment liquid supply unit so that the treatment liquid is supplied from the first tank to the second tank, and
when the treatment liquid is not circulated in the first tank for the set time or longer, the controller controls the treatment liquid supply unit so that the treatment liquid is not supplied from the first tank to the second tank.

14. The apparatus of claim 13, wherein the second tank further includes a second heater installed on the second circulation line.

15. The apparatus of claim 11, wherein the treatment liquid flowing through the first circulation line is at room temperature.

16. The apparatus of claim 14, wherein the first tank further includes a first heater installed in the first circulation line,
the heater installed in the first circulation line heats the treatment liquid to a first temperature,
the heater installed in the second circulation line heats the treatment liquid to a second temperature, and
the second temperature is higher than the first temperature.

17. The apparatus of claim 11, wherein the treatment liquid supply unit further includes a third tank for receiving the treatment liquid from the second tank and storing the treatment liquid,
the liquid supply pipe is a second supply pipe, and
the third tank includes:
a third tank body having a third inner space in which the treatment liquid is stored;
a third circulation line that is connected to the third tank body and circulates the treatment liquid stored in the third inner space;
a third supply pipe for supplying the treatment liquid from the third tank to the liquid treating chamber; and
a third filter and a third heater installed in the third circulation line.

18. A method of processing a substrate by using a substrate processing apparatus including: a liquid treating chamber that processes a substrate by supplying a treatment liquid to a substrate loaded into an inner side; and a liquid supply unit for supplying the treatment liquid to the liquid treating chamber, the liquid supply unit including: a treatment liquid supply source for storing the treatment liquid; a treatment liquid supply pipe for supplying the treatment liquid from the treatment liquid supply source to a first tank; the first tank for receiving the treatment liquid from the treatment liquid supply source and storing the treatment liquid; a second tank for receiving the treatment liquid from the first tank and storing the treatment liquid; and a third tank for receiving the treatment liquid from the second tank and storing the treatment liquid, the first tank including: a first tank body having a first inner space in which the treatment liquid is stored; a first circulation line that is connected to the first tank body and circulates the treatment liquid stored in the first inner space; a first filter and a first heater installed in the first circulation line; and a first supply pipe for supplying the treatment liquid from the first tank to the second tank, the second tank including: a second tank body having a second inner space in which the treatment liquid is stored; a second circulation line that is connected to the second tank body and circulates a raw liquid of the treatment liquid stored in the second inner space; a second filter and a second heater installed in the second circulation line; a second supply pipe for supplying the treatment liquid stored in the second tank to the liquid treating chamber; and a second level sensor for measuring a water level of the treatment liquid in the second inner space, and the third tank including: a third tank body having a third inner space in which the treatment liquid is stored; a third circulation line that is connected to the third tank body and circulates the treatment liquid stored in the third inner space; a third supply pipe for supplying the treatment liquid from the third tank to the liquid treating chamber; and a third filter and a third heater installed in the third circulation line, the method comprising:
supplying a treatment liquid from the treatment liquid supply source to the first tank;
filtering the treatment liquid by circulating the treatment liquid stored in the first tank through the first circulation line;
supplying the treatment liquid from the first tank to the second tank;
supplying the treatment liquid from the second tank to the third tank; and
processing the substrate by supplying the treatment liquid stored in the second tank to the substrate,
wherein when the treatment liquid stored in the first tank is filtered for a set time or longer, the treatment liquid is supplied from the first tank to the second tank, and
the set time is longer as the amount of replenishment of the treatment liquid supplied from the treatment liquid supply source to the first tank increases.

19. The method of claim 18, wherein when a water level of the treatment liquid in the second tank is less than a preset water level, the treatment liquid is supplied from the first tank to the second tank, and
when the treatment liquid is not circulated in the first tank for the set time or longer, the treatment liquid is not supplied from the first tank to the second tank.

20. The method of claim 18, wherein the treatment liquid stored in the first tank is circulated through the first circulation line in which the first heater is installed to heat the treatment liquid to a first temperature,
the treatment liquid is heated to a second temperature by circulating the treatment liquid stored in the second tank through the second circulation line in which the second filter is installed, and
the second temperature is higher than the first temperature.
